(19) United States
(12) Patent Application Publication
(10) Pub. No.: US 2024/0096820 A1
(43) Pub. Date: Mar. 21, 2024

(54) METHOD FOR MANUFACTURING SEMICONDUCTOR PACKAGE USING SACRIFICIAL LAYER AND SEMICONDUCTOR PACKAGE MANUFACTURED BY USING THEREOF

(71) Applicant: SAMSUNG ELECTRONICS CO., LTD., Suwon-si (KR)

(72) Inventors: Young Lyong KIM, Suwon-si (KR); Hyun Soo CHUNG, Suwon-si (KR); In Hyo HWANG, Suwon-si (KR)

(21) Appl. No.: 18/334,100

(22) Filed: Jun. 13, 2023

(30) Foreign Application Priority Data
Sep. 16, 2022 (KR) 10-2022-0116899

(51) Int. Cl. H01L 23/00; H01L 21/56; H01L 23/16; H01L 23/31; H01L 23/498; H01L 23/538; H01L 25/00; H01L 25/065; H10B 80/00

(52) U.S. Cl. CPC H01L 23/562; H01L 21/563; H01L 23/16; H01L 23/3135; H01L 23/49816; H01L 23/5383; H01L 23/5385; H01L 24/16; H01L 24/32; H01L 24/73; H01L 25/0655; H01L 25/50; H10B 80/00; H01L 2224/16225; H01L 2224/32225; H01L 2224/73204

(57) ABSTRACT

A method for manufacturing a semiconductor package includes mounting semiconductor chips on an interposer, forming a molding part between the semiconductor chips, surrounding a plurality of bumps between the semiconductor chips and the interposer with a first underfill, forming a sacrificial layer that covers the semiconductor chips, forming a wafer level molding layer that covers the sacrificial layer, performing a planarization process to expose upper sides of the semiconductor chips, form the sacrificial layer into a sacrificial pattern, and form the wafer level molding layer into a wafer level molding pattern, removing the sacrificial pattern, performing a sawing process to remove an outer edge of the semiconductor package, mounting the interposer on a side of a package board, surrounding a plurality of bumps between the package board and the interposer with a second underfill, and attaching a stiffener to an outer portion of the package board.

### CROSS-REFERENCE TO RELATED APPLICATION

This application claims priority under 35 U.S.C. § 119 to Korean Patent Application No. 10-2022-0116899, filed on Sep. 16, 2022 in the Korean Intellectual Property Office, the entire disclosure of which is incorporated herein by reference in its entirety.

### BACKGROUND

### 1. Field of the Disclosure

The present disclosure relates to methods for manufacturing semiconductor packages using a sacrificial layer and semiconductor packages manufactured using the same.

### 2. Description of the Related Art

Sizes of semiconductor packages are increasing, for example, due to higher specifications of a set, an adoption of high bandwidth memory (HBM), and the use of interposers.

As the size of ae semiconductor package increases, a lateral length of the semiconductor package also increases, and stresses may increase due to a mismatch of coefficients of thermal expansion (CTE) between the interposer and the package board as temperatures change during an operating process.

The increased stresses may add to a local stress for a portion which has different physical properties and very weak adhesion strength, that is, a portion between a chip level underfill and a molding part, thereby generating delamination and cracks.

### SUMMARY

Aspects of the present disclosure provide methods for manufacturing semiconductor packages for preventing occurrence of delamination and cracks between an underfill and a molding part.

Aspects of the present disclosure also provide semiconductor packages which prevent occurrence of delamination and cracks between an underfill and a molding part.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a method for manufacturing a semiconductor package comprising mounting a plurality of semiconductor chips on a first side of an interposer, forming a molding part between the plurality of semiconductor chips, surrounding a plurality of first bumps between the plurality of semiconductor chips and the interposer with a first underfill, forming a sacrificial layer that covers the plurality of semiconductor chips, forming a wafer level molding layer that covers the sacrificial layer, performing a planarization process to expose upper sides of the plurality of semiconductor chips, form the sacrificial layer into a sacrificial pattern, and form the wafer level molding layer into a wafer level molding pattern, removing the sacrificial pattern, performing a sawing process to remove an outer edge of the semiconductor package including the wafer level molding pattern, mounting the interposer on a first side of a package board, surrounding a plurality of second bumps between the package board and the interposer with a second underfill, attaching a stiffener to an outer portion of the first side of the package board, and forming a solder ball on a pad on an opposite, second side of the package board.

According to another aspect of the present disclosure, there is provided a semiconductor package comprising a package board, an interposer mounted on the package board, a plurality of semiconductor chips mounted on the interposer, a stiffener on the package board that extends around the interposer, a first underfill that surrounds a plurality of first bumps between the plurality of semiconductor chips and the interposer, and a second underfill that surrounds a plurality of second bumps between the package board and the interposer, and wherein a thickness of the second underfill on a sidewall of the interposer increases in a direction from a first side of the interposer to an opposite, second side of the interposer.

According to the other aspect of the present disclosure, there is provided a semiconductor package comprising a package board, an interposer mounted on the package board, a plurality of semiconductor chips which include two first semiconductor chips mounted at a center of a first side of the interposer, a plurality of second semiconductor chips mounted on the first side of the interposer adjacent to a first side of the first semiconductor chips, and a plurality of third semiconductor chips mounted on the first side of the interposer adjacent to an opposite, second side of the first semiconductor chips, a stiffener on the package board that extends around the interposer, a first underfill that surrounds a plurality of first bumps between the plurality of semiconductor chips and the interposer, and wherein the first underfill is between the first semiconductor chips, between the first semiconductor chips and the second semiconductor chips, and between the first semiconductor chips and the third semiconductor chips, a molding part between the second semiconductor chips and between the third semiconductor chips, a second underfill that surrounds a plurality of second bumps between the package board and the interposer, and wherein a thickness of the second underfill on a sidewall of the interposer increases in a direction from the first side of the interposer to an opposite second side of the interposer, wherein the interposer has a rectangular configuration with rounded corners and at least one rounded side surface.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a top view of a semiconductor package according to a first embodiment of the present disclosure;

FIG. 2a is a cross-sectional view taken along a line A-A of FIG. 1;

FIG. 2b is an enlarged view of a part I of FIG. 2a;

FIGS. 3 to 14 are exemplary diagrams for explaining a method for manufacturing the semiconductor package according to the first embodiment of the present disclosure;

FIG. 15 is a top view of a semiconductor package according to a second embodiment of the present disclosure;

FIG. 16a is a cross-sectional view taken along line a A2-A2 of FIG. 15;

FIG. 16b is an enlarged view of a part II of FIG. 16a;

FIG. 17 is a cross-sectional view of a semiconductor package according to a third embodiment of the present disclosure;

FIG. 18 is a partially enlarged view of a semiconductor package according to a comparative example of the present disclosure;

FIG. 19 is a partially enlarged view of a semiconductor package according to the first embodiment of the present disclosure; and

FIG. 20 is a stress result graph of a comparative example and the first embodiment of the present disclosure.

### DETAILED DESCRIPTION OF THE EMBODIMENTS

Objects, particular advantages and new features of the present disclosure will become more apparent from the following detailed description and preferred embodiments taken in conjunction with the accompanying drawings. In this specification, when adding reference numbers to the constituent elements of each drawing, it should be noted that only the same constituent elements have the same reference numerals as much as possible even if they are indicated in different drawings. Further, although the terms such as first and second are used to describe various constituent elements, these constituent elements are not limited by these terms. These terms are only used to distinguish a single constituent element from other constituent elements. In addition, in the description of the present disclosure, when it is determined that a detailed description of related known technologies may unnecessarily obscure the gist of the present disclosure, the detailed description thereof will not be provided.

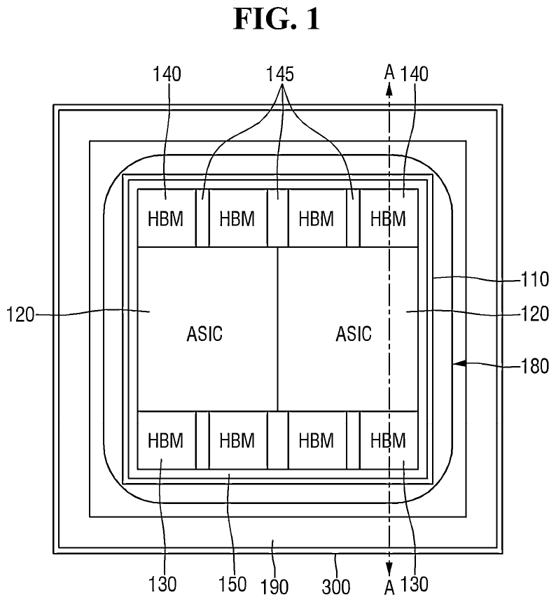

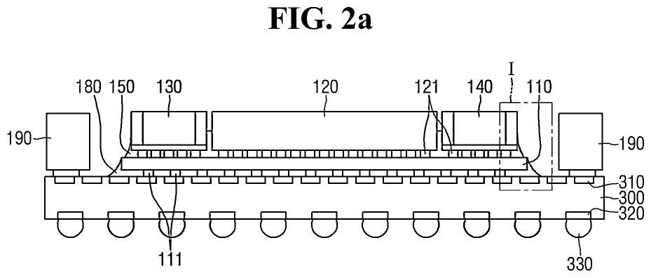

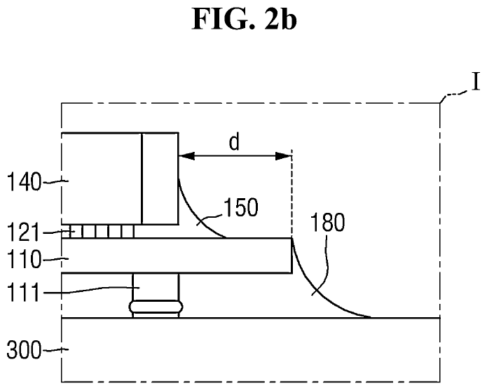

Preferred embodiments of the present disclosure will be described below in detail with reference to the accompanying drawings. FIG. 1 is a top view of a semiconductor package according to a first embodiment of the present disclosure, FIG. 2a is a cross-sectional view taken along a line A-A of FIG. 1, and FIG. 2b is an enlarged view of a part I of FIG. 2a.

The semiconductor package according to the first embodiment of the present disclosure includes a package board 300, an interposer 110 mounted on the package board 300, a plurality of semiconductor chips 120, 130, and 140 mounted on the interposer 110, and a stiffener 190 that surrounds (i.e., extends around) the interposer 110 on the package board 300.

The package board 300 may be, for example, a printed circuit board (PCB). The printed circuit board may be a single-sided board (single-sided PCB) or a double-sided board (double-sided PCB), or a multi-layer board (multi-layer PCB) including one or more internal wiring patterns inside the board. Also, the package board 300 may be a rigid printed circuit board (rigid-PCB) or a flexible printed circuit board (flexible-PCB).

Such a package board 300 may include, for example, epoxy resin, polyimide resin, bismalemide triazine (BT) resin, FR-4 (Flame Retardant 4), FR-5, ceramic, silicon, glass, photosensitive liquid dielectrics, photosensitive dry-film dielectrics, polyimide flexible film thermally cured dry films, thermally cured liquid dielectrics, resin coated copper foil (RCC), thermoplastic or flexible resin.

Alternatively, the package board 300 may be formed by joining or attaching together (e.g., adhesively joining) a plurality of rigid flat plates, or may be formed by joining a thin flexible printed circuit board and a rigid flat plate. A plurality of rigid flat plates or printed circuit boards joined together may each include a wiring pattern. Also, the package board 300 may include an LTCC (low temperature co-fired ceramic) board. The LTCC board may include a plurality of stacked ceramic layers, and may include wiring patterns therein.

The package board 300 may include at least one insulating layer and a metal wiring layer. The metal wiring layer is a circuit pattern formed on the package board 300, and may be formed of, for example, aluminum (Al) or copper (Cu). The surface of such a metal wiring layer may be plated with tin (Sb), gold (Au), nickel (Ni) or lead (Pb).

Further, the package board 300 includes upper pads 310 and lower pads 320 on each of upper and lower sides. The package board 300 is electrically connected to a plurality of semiconductor chips 120, 130, and 140 via the interposer 110 through bumps 111 attached to the upper pads 310, and may electrically connect the package board 300 and an external circuit or the like through the solder balls 330 provided on the lower pads 320. Such upper pads 310 and lower pads 320 may be formed of, for example, aluminum (Al) or copper (Cu), and surfaces thereof may be plated with, for example, tin (Sb), gold (Au), nickel (Ni), lead (Pb) or the like.

In addition, the package board 300 may further include a via structure such as a TCV (Through Core Via) that vertically penetrates and connects at least some of the upper pads 310 and the lower pads 320.

The interposer 110 is a structure mounted on the upper side of the package board 300 in a flip-chip bonding manner using the bumps 111, and is provided for an electrical connection between the plurality of semiconductor chips 120, 130, and 140 and the package board 300.

Such an interposer 110 is a structure including a plurality of insulating layers, a plurality of redistribution layers provided inside the plurality of insulating layers, and a plurality of vias that connect some of the plurality of redistribution layers. The plurality of insulating layers may be formed of a silicon material, an organic compound, or a low dielectric constant (low-k) material having a dielectric constant lower than that of a silicon material.

In particular, when the plurality of insulating layers constituting the interposer 110 are made of organic compounds, the insulating layers may be formed, for example, using thermosetting resins such as acrylate resin, maleimide resin, allyl nadimide resin, phenol resin and epoxy resin, thermoplastic resins such as polyimide, an ABF (Ajinomoto Build-up Film) obtained by mixing such resins with an inorganic filler, or a pre-preg obtained by impregnating reinforcing fibers such as carbon fiber, glass fiber and aramid fiber with thermosetting polymer binder (e.g., epoxy resin) or thermoplastic resin.

Alternatively, optionally, the plurality of insulating layers may use an organic photosensitive insulating material such as, for example, a PID (Photo Imeagable Dielectric) resin. When the plurality of insulating layers are formed of insulating layers having organic photosensitive properties such as a PID resin, each layer may be formed to be thinner, and a fine pitch of vias may be achieved more easily.

The plurality of semiconductor chips 120, 130, and 140 may include, as shown in FIG. 1, two first semiconductor chips 120 mounted at a center of the upper side of the interposer 110, a plurality of second semiconductor chips 130 mounted on the upper side of the interposer 110 to abut against one side of the first semiconductor chips 120, and a plurality of third semiconductor chips 140 mounted on the upper side of the interposer 110 to abut against the other side of the first semiconductor chips 120. The plurality of semiconductor chips 120, 130, and 140 may be mounted on the upper side of the interposer 110 by various placement structures, without being limited to the placement structure shown in FIG. 1.

The first semiconductor chip 120 is a logic semiconductor chip, and may be a microprocessor. The first semiconductor chip 120 may be, for example, a central processing unit (CPU), a controller or an application specific integrated circuit (ASIC).

The second semiconductor chip 130 and the third semiconductor chip 140 are memory semiconductor chips, and may be, for example, a HBM (High Bandwidth Memory) semiconductor chip. In particular, the second semiconductor chip 130 and the third semiconductor chip 140 may include a plurality of stacked memory semiconductor chips. Each of the plurality of memory semiconductor chips may be, for example, a volatile memory semiconductor chip such as a DRAM (Dynamic Random Access Memory) or a SRAM (Static Random Access Memory), or a non-volatile memory semiconductor chip such as a PRAM (Phase-change Random Access Memory), a MRAM (Magnetoresistive Random Access Memory), a FeRAM (Ferroelectric Random Access Memory) or a RRAM (Resistive Random Access Memory). However, the technical idea of the present disclosure is not limited thereto.

A gap between the two first semiconductor chips 120, a gap between the first semiconductor chip 120 and the second semiconductor chip 130, and a gap between the first semiconductor chip 120 and the third semiconductor chip 140 are provided as spaced intervals of 4 to 60 μm. The spaced intervals are filled with a first underfill 150, which will be described below.

The plurality of semiconductor chips 120, 130, and 140 may be mounted on the upper side of the interposer 110 in a flip-chip bonding manner or a wire bonding manner. However, this is an example, and the embodiment is not limited thereto.

When the plurality of semiconductor chips 120, 130, and 140 are mounted in the flip-chip bonding manner, each of the plurality of semiconductor chips 120, 130, and 140 may be connected to the interposer 110 through the bumps 121, and active sides of each of the plurality of semiconductor chips 120, 130, and 140 may be attached to face the interposer 110.

A molding part 145 is formed by filling the gap between the second semiconductor chips 130 and the gap between the third semiconductor chips 140 among the plurality of semiconductor chips 120, 130 and 140 with a molding material. The molding part 145 may be formed, for example, using an EMC (Epoxy Molding Compound) or silicon hybrid materials of different kinds or more through a MUF (Molded Under Fill) process. In addition, the molding part 145 may further include a filler, and the filler may include at least one selected from silicon oxide, calcium carbonate, magnesium carbonate, alumina, magnesia, clay, alumina (Al₂O₃), titania (TiO₂), talc, calcium silicate, antimony oxide, glass fiber and eucryptite ceramic.

The MUF process refers to a process that fills the spaces between the plurality of semiconductor chips 120, 130, and 140 and the interposer 110 with the molding part 145 together, without separately performing a process of filling the space between the plurality of semiconductor chips 120, 130, and 140 and the interposer 110 with an under fill.

The molding part 400 may be formed by processes other than the MUF process. That is, the molding may be performed by a process of first filling the molding material between the plurality of semiconductor chips 120, 130, and 140 and the interposer 110 with the under fill, and then, covering the spaces between the side walls of the plurality of semiconductor chips 120, 130, and 140 with the molding material.

The stiffener 190 may be placed on the package board 300 in the form that surrounds the outer portion of the upper side of the package board 300. For example, a horizontal cross section of the stiffener 190 may be provided in the form of a rectangular ring that surrounds the plurality of semiconductor chips 120, 130, and 140 and the interposer 110 placed at the central portion as shown in FIG. 1. However, the shape of the horizontal cross section of stiffener 190 is not limited to the rectangular ring shape. In addition, a vertical cross-section of stiffener 190 may have a rectangular shape as shown in FIG. 2a. The stiffener 190 may improve the thermal properties of the package board 300, for example, wrapper paper properties of the package board 300, by mechanically supporting the package board 300.

Such a stiffener 190 may include metals such as steel or copper (Cu). However, the material of the stiffener 190 is not limited thereto. The stiffener 190 may be attached to the package board 300 through an adhesive layer. The upper side of the stiffener 190 may be lower than the upper sides of the plurality of semiconductor chips 120, 130, and 140. However, according to embodiments, the upper side of the stiffener 190 may have substantially the same height as the upper sides of the plurality of semiconductor chips 120, 130, and 140, or may be higher than the upper sides of the plurality of semiconductor chips 120, 130, and 140.

As shown in FIGS. 2a and 2b, the semiconductor package according to the first embodiment of the present disclosure configured as described above includes a first underfill 150 which is filled to surround a plurality of bumps 121 between the plurality of semiconductor chips 120, 130 and 140 and the interposer 110 and is filled between the two first semiconductor chips 120, between the first semiconductor chip 120 and the second semiconductor chip 130, and between the first semiconductor chip 120 and the third semiconductor chip 140, and a second underfill 180 which is filled to surround the plurality of bumps 111 between the interposer 110 and the package board 300.

The first underfill 150 and the second underfill 180 may be formed, using epoxy-series resin, benzocyclobutyne resin or polyimide resin. However, the first underfill 150 and the second underfill 180 are not limited thereto, and may further include a filler, and may include an adhesive and flux. The flux may include an oxide film remover.

The filler may include at least one selected from silicon oxide, calcium carbonate, magnesium carbonate, alumina, magnesia, clay, alumina (Al₂O₃), titania (TiO₂), talc, calcium silicate, antimony oxide, glass fiber and eucryptite ceramic.

The fillers included in the first underfill 150 and the second underfill 180 are provided to have a smaller size than the fillers included in the molding part 145. That is, the filler included in the molding part 145 has a size that is 1.5 times greater than the fillers included in the first underfill 150 and the second underfill 180.

The first underfill 150 is formed between the two first semiconductor chips 120, between the first semiconductor chip 120 and the second semiconductor chip 130, and between the first semiconductor chip 120 and the third semiconductor chip 140.

In addition, a cavity width d from an upper edge of the interposer 110 provided with the end of the first underfill 150 to a side wall of the semiconductor chip is formed to have a maximum width of 50 μm, thereby providing a margin in a lateral direction.

Also, as shown in FIG. 2b, the second underfill 180 is provided in the form of a tapered pattern whose thickness to the upper side of the interposer 110 with respect to the side walls of the interposer 110 becomes thinner.

Since the components forming the semiconductor package have different coefficients of thermal expansion (CTE) by the form of the first underfill 150 and the second underfill 180, an occurrence of cracks in the underfill can be prevented.

That is, as the size of the package board 300 increases, a stress due to mismatch caused by different coefficients of thermal expansion of the components forming the semiconductor package is transferred, thereby causing delamination and cracks between the components.

However, since a cavity is formed at the upper edge of the interposer 110 in which the end of the first underfill 150 is provided, and the second underfill 180 is provided in the form of a tapered pattern, a stress is reduced due to the structures separated from each other, and the generated stress is not transferred. Accordingly, the thermal life can be improved.

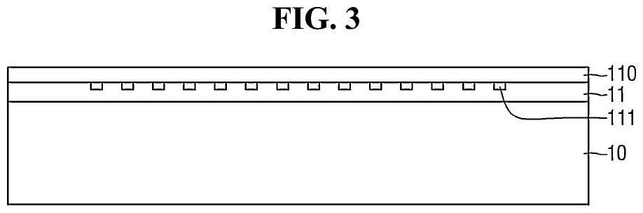

A method for manufacturing a semiconductor package according to the first embodiment of the present disclosure will be described below with reference to FIGS. 3 to 14. FIGS. 3 to 14 are exemplary diagrams for explaining the method for manufacturing the semiconductor package according to the first embodiment of the present disclosure.

In the method for manufacturing the semiconductor packing according to the first embodiment of the present disclosure, first, as shown in FIG. 3, a carrier board 10 having a release layer 11 on its upper side is provided.

The carrier board 10 may be a board of a structure including a core layer and a metal film formed on the core layer, and the release layer 11 is a layer that is provided for an easy separation of the interposer 110 from the carrier board 10 in a subsequent process step, and may be, for example, a layer made of a composition that is releasable by a laser. The release layer 11 may use a generally releasable composition in addition to the composition that is releasable by the laser.

The interposer 110 is attached to the upper side of the carrier board 10 having the release layer 11 as described above. As a result, the release layer 11 impregnates the bumps 111 of the interposer 110 and is attached to the lower side of the interposer 110.

The interposer 110 may be attached to the upper side of the carrier board 10 that is provided by being manufactured in advance and has the release layer 11. Such an interposer 110 is a structure including a plurality of insulating layers, a plurality of redistribution layers provided in the plurality of insulating layers, and a plurality of vias that connect some of the plurality of redistribution layers. The plurality of insulating layers may be formed of a silicon material, an organic compound, or a low dielectric constant (low-k) material having a dielectric constant lower than that of a silicon material.

In particular, when the plurality of insulating layers constituting the interposer 110 are made of organic compounds, the insulating layers may be formed, for example, using thermosetting resins such as acrylate resin, maleimide resin, allyl nadimide resin, phenol resin and epoxy resin, thermoplastic resins such as polyimide, an ABF (Ajinomoto Build-up Film) obtained by mixing such resins with an inorganic filler, or a pre-preg obtained by impregnating reinforcing fibers such as carbon fiber, glass fiber and aramid fiber with thermosetting polymer binder (e.g., epoxy resin) or thermoplastic resin. Alternatively, optionally, the plurality of insulating layers may use an organic photosensitive insulating material such as, for example, a PID (Photo Imeagable Dielectric) resin. When the plurality of insulating layers are formed of insulating layers having organic photosensitive properties such as a PID resin, each layer may be formed to be thinner, and a fine pitch of vias may be achieved more easily.

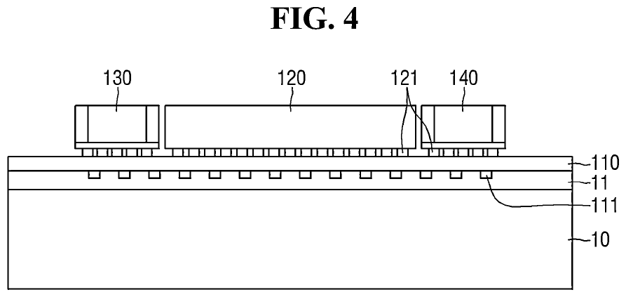

After attaching the interposer 110, a plurality of semiconductor chips 120, 130, and 140 are mounted on the upper side of the interposer 110 as shown in FIG. 4.

The plurality of semiconductor chips 120, 130, and 140 may include, as in FIG. 1, two first semiconductor chips 120 mounted at a center of the upper side of the interposer 110, a plurality of second semiconductor chips 130 mounted on the upper side of the interposer 110 to abut against one side of the first semiconductor chips 120, and a plurality of third semiconductor chips 140 mounted on the upper side of the interposer 110 to abut against the other side of the first semiconductor chips 120. The plurality of semiconductor chips 120, 130, and 140 may be mounted on the upper side of the interposer 110 by various placement structures, without being limited to such a placement structure.

The first semiconductor chip 120 is a logic semiconductor chip, and may be a microprocessor. The first semiconductor chip 120 may be, for example, a central processing unit (CPU), a controller or an application specific integrated circuit (ASIC).

The second semiconductor chip 130 and the third semiconductor chip 140 are memory semiconductor chips, and may be, for example, HBM (High Bandwidth Memory) semiconductor chips. In particular, the second semiconductor chip 130 and the third semiconductor chip 140 may include a plurality of stacked memory semiconductor chips. Each of the plurality of memory semiconductor chips may be, for example, a volatile memory semiconductor chip such as a DRAM (Dynamic Random Access Memory) or a SRAM (Static Random Access Memory), or a non-volatile memory semiconductor chip such as a PRAM (Phase-change Random Access Memory), a MRAM (Magnetoresistive Random Access Memory), a FeRAM (Ferroelectric Random Access Memory) or a RRAM (Resistive Random Access Memory). However, the technical idea of the present disclosure is not limited thereto.

The plurality of semiconductor chips 120, 130, and 140 are mounted on the upper side of the interposer 110 through the bumps 111 in the flip-chip bonding manner.

After mounting the plurality of semiconductor chips 120, 130 and 140, the molding part 145 is formed between the plurality of semiconductor chips 120, 130 and 140. The molding part 145 may be formed, for example, using an EMC (Epoxy Molding Compound) or silicon hybrid materials of different kinds or more through a MUF (Molded Under Fill) process. In addition, the molding part 145 may further include a filler, and the filler may include at least one selected from silicon oxide, calcium carbonate, magnesium carbonate, alumina, magnesia, clay, alumina (Al₂O₃), titania (TiO₂), talc, calcium silicate, antimony oxide, glass fiber and eucryptite ceramic.

The MUF process refers to a process that fills spaces between the plurality of semiconductor chips 120, 130, and 140 and the interposer 110 with the molding part 145 together, without separately performing a process of filling the space between the plurality of semiconductor chips 120, 130, and 140 and the interposer 110 with an under fill.

The molding part 145 may be formed by processes other than the MUF process. That is, the molding part 145 may be formed by a process of first filling the molding material between the plurality of semiconductor chips 120, 130, and 140 and the interposer 110 with the under fill, and then, covering the spaces between the side walls of the plurality of semiconductor chips 120, 130, and 140 with the molding material.

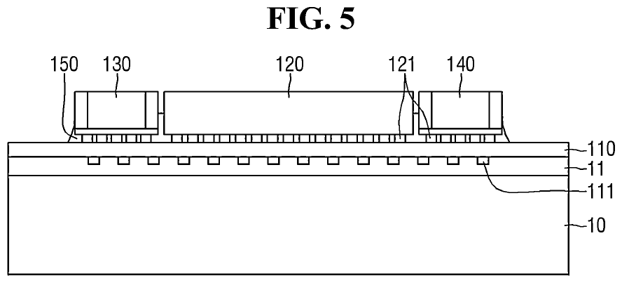

After forming the molding part 145, as shown in FIG. 5, a first underfill 150 is filled between the two first semiconductor chips 120, between the first semiconductor chip 120 and the second semiconductor chip 130, and between the first semiconductor chip 120 and the third semiconductor chip 140 to surround the plurality of bumps 121 between the plurality of semiconductor chips 120, 130, and 140 and the interposer 110.

Specifically, the first underfill 150 may be formed, using epoxy-series resin, benzocyclobutyne resin or polyimide resin, may further include a filler, and may include an adhesive and flux. The flux may include an oxide film remover.

The filler may include at least one selected from silicon oxide, calcium carbonate, magnesium carbonate, alumina, magnesia, clay, alumina (Al₂O₃), titania (TiO₂), talc, calcium silicate, antimony oxide, glass fiber and eucryptite ceramic.

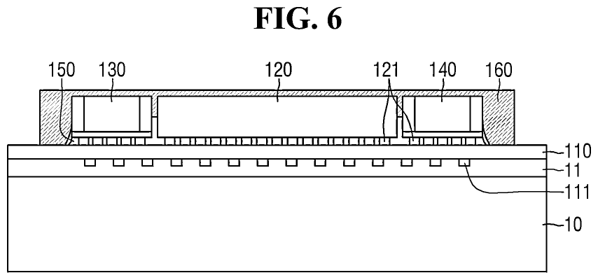

After forming the first underfill 150, a sacrificial layer 160 that covers the plurality of semiconductor chips 120, 130 and 140 is formed on the upper side of the interposer 110 as shown in FIG. 6.

Specifically, the sacrificial layer 160 may be formed using a PR (photoresist), and such a PR may be divided into, for example, a positive type PR including a mixture of diazonaphthoquinone (DNQ) and a novolak resin, and a negative type PR including an epoxy resin. The sacrificial layer 160 uses the positive type PR that is easily dissolved in a developer.

The sacrificial layer 160 may be formed by dispensing the positive type PR using a dispenser to cover the plurality of semiconductor chips 120, 130, and 140 on the upper side of the interposer 110, and then performing a soft cure process.

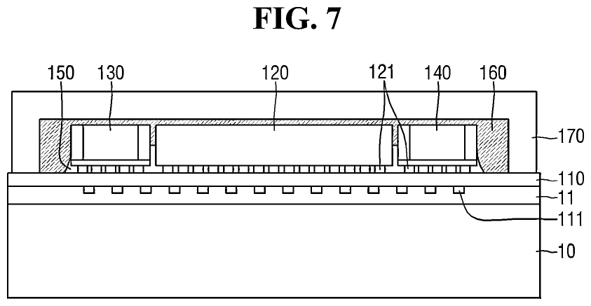

After forming the sacrificial layer 160, a wafer level molding layer 170 that covers the sacrificial layer 160 is formed on the upper side of the interposer 110 as shown in FIG. 7.

The wafer level molding layer 170 may be formed to cover the sacrificial layer 160 on the upper side of the interposer 110 using, for example, an EMC (Epoxy Molding Compound) or silicon hybrid materials of different kinds or more. Such a wafer level molding layer 170 may further include a filler, and the filler may include at least one selected from silicon oxide, calcium carbonate, magnesium carbonate, alumina, magnesia, clay, alumina (Al₂O₃), titania (TiO₂), talc, calcium silicate, antimony oxide, glass fiber and eucryptite ceramic.

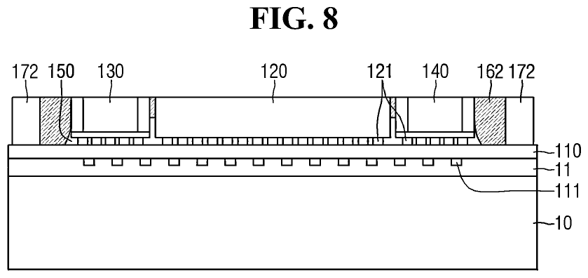

After forming the wafer level molding layer 170, as shown in FIG. 8, the upper sides of the plurality of semiconductor chips 120, 130, and 140 are exposed, using back grinding, a CMP (Chemical Mechanical Polishing) process, an etch-back process, or the like, as shown in FIG. 8.

Accordingly, the sacrificial layer 160 remains as the sacrificial pattern 162, and the wafer level molding layer 170 remains as a wafer level molding pattern 172. The remaining sacrificial pattern 162 is provided in the form that fills a region including a cavity, which will be described below.

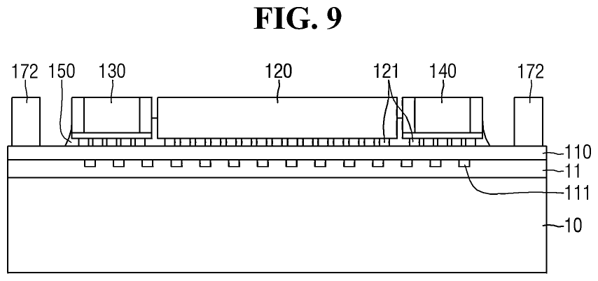

A developer is spin-coated to remove the remaining sacrificial pattern 162, and the developer may permeate along the exposed upper side of the sacrificial pattern 162 to remove the sacrificial pattern 162, as shown in FIG. 9.

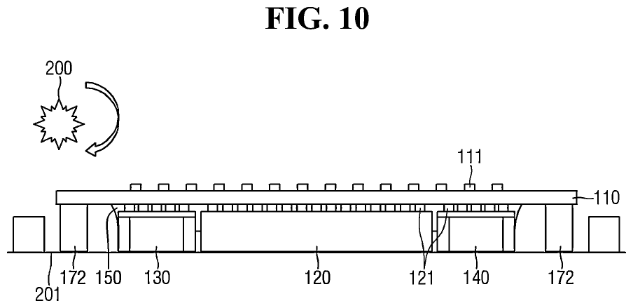

After removing the sacrificial pattern 162, the carrier board 10 is removed, using the release layer 11 as shown in FIG. 10, and a dicing tape 201 is attached to the upper sides of the plurality of semiconductor chips 120, 130 and 140 and the upper side of the wafer level molding pattern 172.

The dicing tape 201 is an adhesive tape having a ring-shaped metal pattern of a certain height along the edge, and prevents shaking of the tape by the ring-shaped metal pattern to facilitate attachment.

With the dicing tape 201 attached, a sawing process using a blade 200 or a laser is performed. The outer edge portion including the wafer level molding pattern 172 is removed, by the sawing process.

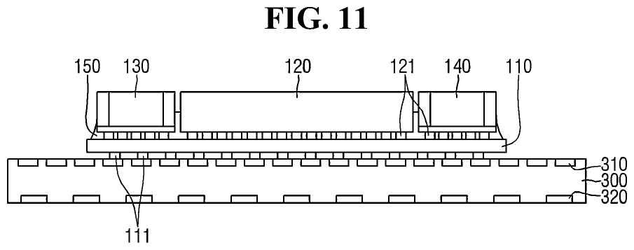

After performing the sawing process, the structure of the plurality of separated semiconductor chips 120, 130, and 140 and the interposer 110 is mounted on the upper side of the package board 300 as shown in FIG. 11.

The package board 300 may be, for example, a printed circuit board (PCB). The printed circuit board may be a single-sided board (single-sided PCB) or a double-sided board (double-sided PCB), or a multi-layer board (multi-layer PCB) including one or more internal wiring patterns in the board. Also, the package board 300 may be a rigid printed circuit board (rigid-PCB) or a flexible printed circuit board (flexible-PCB).

The package board 300 includes upper pads 310 and lower pads 320 on each of upper and lower sides, may be electrically connected to a plurality of semiconductor chips 120, 130, and 140 via an interposer 110 through bumps 111 attached to the upper pads 310, and may electrically connect the package board 300 and an external circuit or the like through the solder balls 330 provided on the lower pads 320. Each upper pad 310 and lower pad 320 may be formed of, for example, aluminum (Al) or copper (Cu), and surfaces thereof may be plated with, for example, tin (Sb), gold (Au), nickel (Ni), lead (Pb) or the like.

The package board 300 may further include a via structure such as a TCV (Through Core Via) that vertically penetrates and connects at least some of the upper pads 310 and the lower pads 320.

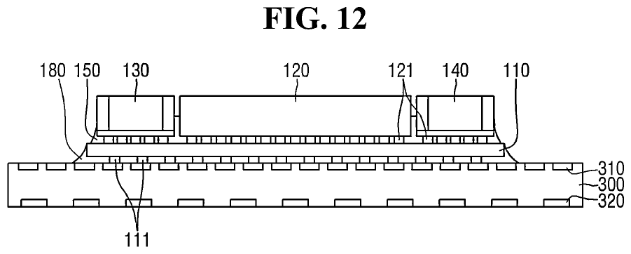

After mounting on the upper side of the package board 300, as shown in FIG. 12, a second underfill 180 is filled to surround the plurality of bumps 111 between the package board 300 and the interposer 110.

Specifically, the second underfill 180 may be formed, for example, using epoxy-series resin, benzocyclobutyne resin or polyimide resin, may further include a filler, and may include an adhesive and flux. The flux may include an oxide film remover.

The filler may include at least one selected from silicon oxide, calcium carbonate, magnesium carbonate, alumina, magnesia, clay, alumina (Al₂O₃), titania (TiO₂), talc, calcium silicate, antimony oxide, glass fiber and eucryptite ceramic.

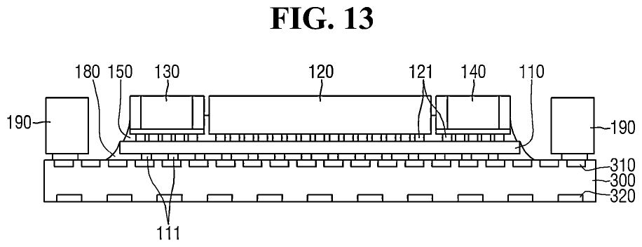

After filling the second underfill 180, a stiffener 190 is attached along the outer portion of the upper side of the package board 300 as shown in FIG. 13.

The stiffener 190 is placed on the upper side of the package board 300 to surround the structure of the plurality of semiconductor chips 120, 130, and 140 and the interposer 110. For example, a horizontal cross section of the stiffener 190 may be provided in the form of a rectangular ring that surrounds the plurality of semiconductor chips 120, 130, and 140 and the interposer 110 placed at the central portion as shown in FIG. 1.

However, the shape of the horizontal cross section of the stiffener 190 is not limited to a rectangular ring shape. A vertical cross-section of the stiffener 190 may have a rectangular shape. The stiffener 190 may improve the thermal properties of the package board 300, for example, wrapper paper properties of the package board 300, by mechanically supporting the package board 300.

Such a stiffener 190 may be formed of metals such as steel or copper (Cu). However, the material of the stiffener 190 is not limited thereto. The stiffener 190 may be attached to the package board 300 through an adhesive layer. The upper side of the stiffener 190 may be lower than the upper sides of the plurality of semiconductor chips 120, 130, and 140. However, according to embodiments, the upper side of the stiffener 190 may have substantially the same height as the upper sides of the plurality of semiconductor chips 120, 130, and 140, or may be higher than the upper sides of the plurality of semiconductor chips 120, 130, and 140.

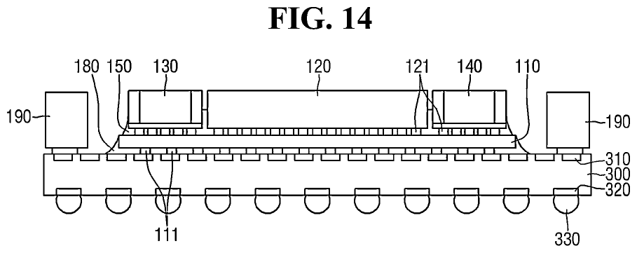

After mounting the stiffener 190, the solder balls 330 are formed on the lower pads 320 provided in the lower part of the package board 300, as shown in FIG. 14.

The semiconductor package may be mounted on various electronic devices, for example, a motherboard, using such solder balls 330, and the package board 300 may be electrically connected to an external circuit of the electronic device through the solder balls 330.

In the method for manufacturing the semiconductor package according to the first embodiment of the present disclosure, since a cavity is formed from the upper edge of the interposer 110 to the side wall of the semiconductor chip, and the second underfill 180 is formed in the form of a tapered pattern whose thickness to the upper side of the interposer 110 with respect to the side wall of the interposer 110 becomes thinner, it is possible to provide a semiconductor package that prevents cracks from occurring in the underfill due to different coefficients of thermal expansion.

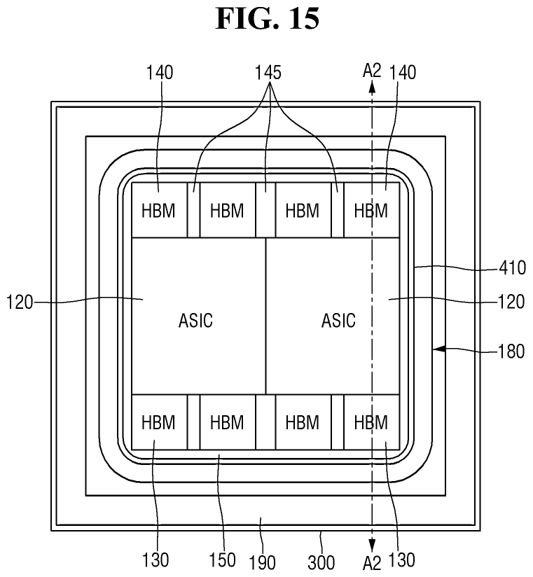

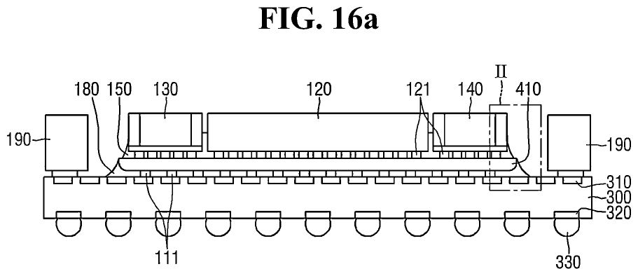

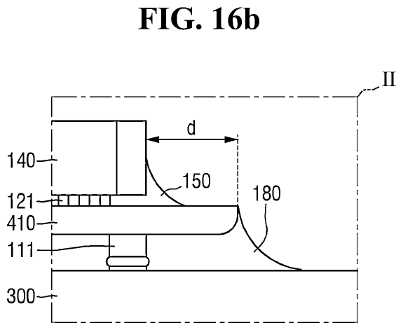

A semiconductor package according to a second embodiment of the present disclosure will be described below with reference to FIGS. 15 to 16b. FIG. 15 is a top view of a semiconductor package according to the second embodiment of the present disclosure, FIG. 16a is a cross-sectional view taken along line A2-A2 of FIG. 15, and FIG. 16b is an enlarged view of a portion II of FIG. 16a.

The semiconductor package according to the second embodiment of the present disclosure includes a package board 300, an interposer 410 mounted on the package board 300, a plurality of semiconductor chips 120, 130, and 140 mounted on the interposer 410, and a stiffener 190 that surrounds the interposer 410 on the package board 300, similarly to the semiconductor package according to the first embodiment of the present disclosure.

However, the semiconductor package according to the second embodiment of the present disclosure is characterized in that the interposer 410 has a shape in which each of four corners is rounded on a plane as shown in FIG. 15, and has a shape in which a lower corner is rounded on a side surface as shown in FIG. 16b.

As the four corners of the interposer 410 have a rounded shape in this way, the first underfill 150 and the second underfill 180 are also provided in the rounded shape along the edges of the interposer 410 as shown in FIG. 15.

Local stress can be dispersed due to the rounded shape of the interposer 410, and thus, it is possible to further prevent cracks from being generated and transferred to the second underfill 180 provided in the form of a tapered pattern whose thickness to the upper side with respect to the side walls of the interposer 410 becomes thinner.

Therefore, the semiconductor package according to the second embodiment of the present disclosure can further prevent delamination or cracks from being generated and transferred to the underfill due to different coefficients of thermal expansion, by the cavity having the width d from the upper edge of the interposer 410 to the side wall of the semiconductor chip 140, the second underfill 180 provided in the form of a tapered pattern whose thickness to the upper side of the interposer 410 with respect to the side wall of the interposer 410 becomes thinner, and the interposer 410 provided in a rounded shape.

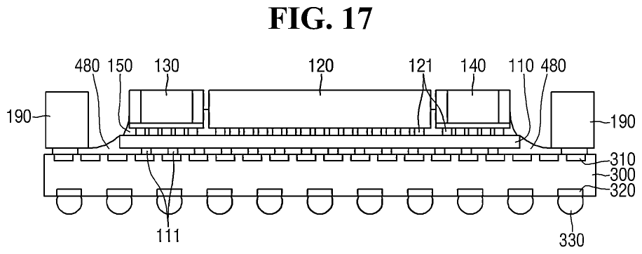

A semiconductor package according to a third embodiment of the present disclosure will be described below with reference to FIG. 17. FIG. 17 is a cross-sectional view of a semiconductor package according to the third embodiment of the disclosure.

The semiconductor package according to the third embodiment of the present disclosure includes a package board 300, an interposer 110 mounted on the package board 300, a plurality of semiconductor chips 120, 130, and 140 mounted on the interposer 110, and a stiffener 190 that surrounds the interposer 110 on the package board 300, similarly to the semiconductor package according to the first embodiment of the present disclosure.

However, the semiconductor package according to the third embodiment of the present disclosure is characterized in that a second underfill 480 is provided in the form of a tapered pattern whose thickness to the upper side with respect to the side wall of the interposer 110 becomes thinner, and the other side is provided to abut against the stiffener 190.

The second underfill 480 may be formed, for example, using epoxy-series resin, benzocyclobutyne resin or polyimide resin, may further include a filler, an adhesive and flux. The flux may include an oxide film remover.

The filler may include at least one selected from silicon oxide, calcium carbonate, magnesium carbonate, alumina, magnesia, clay, alumina (Al₂O₃), titania (TiO₂), talc, calcium silicate, antimony oxide, glass fiber and eucryptite ceramic.

The second underfill 480 may be provided in the form that covers the outer upper side of the package board 300 and the inner lower part of the stiffener 190, thereby improving durability against physical or chemical impact.

Therefore, the semiconductor package according to the third embodiment of the present disclosure can improve the durability against physical or chemical impact, while preventing delamination or cracking from being generated and transferred to the underfill due to different coefficients of thermal expansion, by the cavity having a width d from the upper edge of the interposer 110 to the side wall of the semiconductor chip, and the second underfill 480 which is provided in the form of a tapered pattern whose a thickness to the upper side of the interposer 110 with respect to the side wall of the interposer 110 becomes thinner, and covers the outer upper side of the package board 300 and the inner lower part of the stiffener 190.

As described above, the semiconductor packages according to some embodiments of the present disclosure have the effect of preventing the stress caused by the mismatch due to the different coefficients of thermal expansion from being transferred and causing delamination or cracking between the components.

This effect may be confirmed through stress simulations on a semiconductor package according to a comparative example of the present disclosure to be described below and the semiconductor package according to the first embodiment of the present disclosure.

### COMPARATIVE EXAMPLE

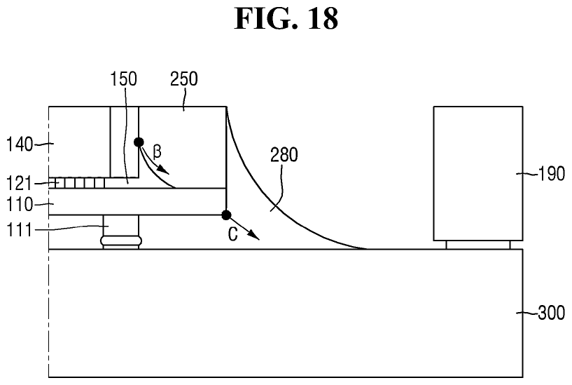

A semiconductor package according to the comparative example of the present disclosure relates to a conventional semiconductor package structure, and as shown in FIG. 18, includes a package board 300, an interposer 110 mounted on the package board 300, a plurality of semiconductor chips 120, 130, and 140 mounted on the interposer 110, and a stiffener 190 that surrounds the interposer 110 on the package board 300, a molding member 250 that covers the first underfill 150 is provided on an upper edge of the interposer, and a second underfill 280 is provided along the side walls of the molding member 250 and the side walls of the interposer 110.

### Example

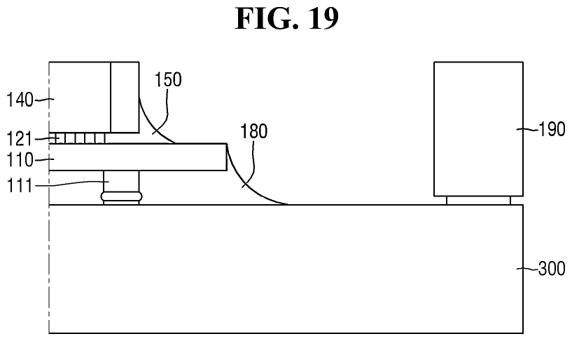

As a semiconductor package according to the first embodiment of the present disclosure, as shown in FIG. 19, the semiconductor package includes the package board 300, the interposer 110 mounted on the package board 300, the plurality of semiconductor chips 120, 130, and 140 mounted on the interposer 110, and the stiffener 190 that surrounds the interposer 110 on the package board 300, has a cavity in which the upper part of the first underfill 150 is empty from the upper edge of the interposer 110 to the side wall of the semiconductor chip, and forms a second underfill 180 having the form of a tapered pattern whose thickness to the upper side of the interposer 110 on the side wall of the interposer 110 becomes thinner.

For each of the semiconductor package according to the comparative example of the present disclosure and the semiconductor package according to the first embodiment of the present disclosure, the degree of stress occurrence may be confirmed using Ansys model simulation.

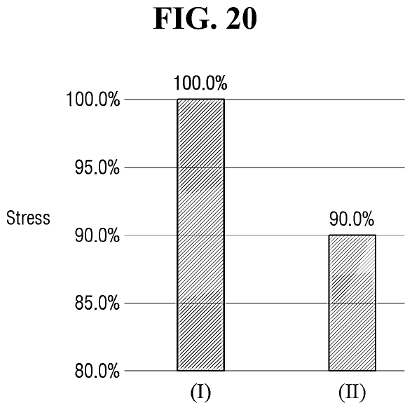

As a result of this simulation, as shown in FIG. 20, the stress on the semiconductor package according to the comparative example of the present disclosure is represented by graph I, and the stress on the semiconductor package according to the first embodiment of the present disclosure is represented by graph II.

As may be seen from the stress result graph, the stress on the semiconductor package according to the comparative example of the present disclosure was 100%, while the stress on the semiconductor package according to the first embodiment of the present disclosure was definitely reduced to 90%.

These results show that stress due to mismatch caused by different coefficients of thermal expansion is generated and transferred in the semiconductor package according to the comparative example of the present disclosure, as indicated by “B” and “C” in FIG. 18, meanwhile, in the semiconductor package according to the first embodiment of the present disclosure, the generated stress is not transferred by the cavity and the structure of the second underfill 180 having the form of the tapered pattern, and the stress is definitely reduced.

Although the technical idea of the present disclosure has been specifically described according to the above preferred embodiments, it should be noted that the above embodiments are for explanation and not for limitation.

Further, it will be understood by those skilled in the art of the technical field of the present disclosure that various implementations are possible within the scope of the technical concept of the present disclosure.

What is claimed is:

1. A method for manufacturing a semiconductor package, the method comprising:
mounting a plurality of semiconductor chips on a first side of an interposer;
forming a molding part between the plurality of semiconductor chips;
surrounding a plurality of first bumps between the plurality of semiconductor chips and the interposer with a first underfill;
forming a sacrificial layer that covers the plurality of semiconductor chips;
forming a wafer level molding layer that covers the sacrificial layer;
performing a planarization process to expose upper sides of the plurality of semiconductor chips, form the sacrificial layer into a sacrificial pattern, and form the wafer level molding layer into a wafer level molding pattern;
removing the sacrificial pattern;
performing a sawing process to remove an outer edge of the semiconductor package including the wafer level molding pattern;
mounting the interposer on a first side of a package board;
surrounding a plurality of second bumps between the package board and the interposer with a second underfill;
attaching a stiffener to an outer portion of the first side of the package board; and
forming a solder ball on a pad on an opposite, second side of the package board.

2. The method for manufacturing the semiconductor package of claim 1,
wherein the plurality of semiconductor chips comprise two first semiconductor chips mounted at a center of the first side of the interposer, a plurality of second semiconductor chips mounted on the first side of the interposer adjacent to a first side of the first semiconductor chips, and a plurality of third semiconductor chips mounted on the first side of the interposer adjacent to an opposite, second side of the first semiconductor chip.

3. The method for manufacturing the semiconductor package of claim 2,
wherein the forming the molding part between the plurality of semiconductor chips comprises providing a molding material between the second semiconductor chips and between the third semiconductor chips, wherein the molding material comprises an EMC (Epoxy Molding Compound) or silicon hybrid materials.

4. The method for manufacturing the semiconductor package of claim 1,
wherein the first underfill and the second underfill comprise underfill resin, filler, adhesive and flux, and
wherein the molding part comprises a filler having a size greater than 1.5 times that of the filler in the first underfill and the second underfill.

5. The method for manufacturing the semiconductor package of claim 1,
wherein the sacrificial layer comprises a positive type PR (photo resist) that dissolves in a developer.

6. The method for manufacturing the semiconductor package of claim 1,
wherein the sacrificial pattern is within a region defined by an edge of the interposer and side walls of the plurality of semiconductor chips adjacent the edge of the interposer.

7. The method for manufacturing the semiconductor package of claim 1,
wherein the interposer comprises a plurality of insulating layers, a plurality of redistribution layers inside the plurality of insulating layers, and a plurality of vias that connect some of the plurality of redistribution layers, and wherein the plurality of insulating layers comprise any one of a silicon material, an organic compound, and a low dielectric constant (low-k) material having a dielectric constant lower than that of the silicon material.

8. The method for manufacturing the semiconductor package of claim 2,
wherein the surrounding the plurality of first bumps between the plurality of semiconductor chips and the interposer with the first underfill comprises providing the first underfill between the first semiconductor chips, between the first semiconductor chips and the second semiconductor chips, and between the first semiconductor chips and the third semiconductor chips.

9. The method for manufacturing the semiconductor package of claim 1,
wherein a thickness of the second underfill on a sidewall of the interposer increases in a direction from the first side of the interposer to an opposite, second side of the interposer.

10. A semiconductor package comprising:
a package board;
an interposer mounted on the package board;
a plurality of semiconductor chips mounted on the interposer;
a stiffener on the package board that extends around the interposer;
a first underfill that surrounds a plurality of first bumps between the plurality of semiconductor chips and the interposer; and
a second underfill that surrounds a plurality of second bumps between the package board and the interposer, and wherein a thickness of the second underfill on a sidewall of the interposer increases in a direction from a first side of the interposer to an opposite, second side of the interposer.

11. The semiconductor package of claim 10,
wherein the plurality of semiconductor chips comprise two first semiconductor chips mounted at a center of the first side of the interposer, a plurality of second semiconductor chips mounted on the first side of the interposer adjacent to a first side of the first semiconductor chips, and a plurality of third semiconductor chips mounted on the first side of the interposer adjacent to an opposite, second side of the first semiconductor chips.

12. The semiconductor package of claim 11,
wherein the first semiconductor chips comprise an ASIC (application specific integrated circuit), and
wherein the second semiconductor chips and the third semiconductor chips comprise a HBM (High Bandwidth Memory) semiconductor chip.

13. The semiconductor package of claim 11, further comprising:
a molding part between the second semiconductor chips and between the third semiconductor chips.

14. The semiconductor package of claim 13,
wherein the molding part comprises a filler having a size greater than 1.5 times a filler in the first underfill and second underfill.

15. The semiconductor package of claim 10,
wherein the interposer comprises a plurality of insulating layers, a plurality of redistribution layers inside the plurality of insulating layers, and a plurality of vias that connect some of the plurality of redistribution layers, and wherein the plurality of insulating layers comprise any one of a silicon material, an organic compound, and a low dielectric constant (low-k) material having a dielectric constant lower than that of the silicon material.

16. The semiconductor package of claim 11,
wherein the first underfill is between the first semiconductor chips, between the first semiconductor chips and the second semiconductor chips, and between the first semiconductor chips and the third semiconductor chips.

17. The semiconductor package of claim 10,
wherein a region defined by an edge of the interposer and side walls of the plurality of semiconductor chips has a width that is greater than 50 μm.

18. The semiconductor package of claim 10,
wherein the second underfill covers an outer portion of a first side of the package board and an inner portion of the stiffener.

19. A semiconductor package comprising:
a package board;
an interposer mounted on the package board;
a plurality of semiconductor chips comprising two first semiconductor chips mounted at a center of a first side of the interposer, a plurality of second semiconductor chips mounted on the first side of the interposer adjacent to a first side of the first semiconductor chips, and a plurality of third semiconductor chips mounted on the first side of the interposer adjacent to an opposite, second side of the first semiconductor chips;
a stiffener on the package board that extends around the interposer;
a first underfill that surrounds a plurality of first bumps between the plurality of semiconductor chips and the interposer, and wherein the first underfill is between the first semiconductor chips, between the first semiconductor chips and the second semiconductor chips, and between the first semiconductor chips and the third semiconductor chips;
a molding part between the second semiconductor chips and between the third semiconductor chips; and
a second underfill that surrounds a plurality of second bumps between the package board and the interposer, and wherein a thickness of the second underfill on a sidewall of the interposer increases in a direction from the first side of the interposer to an opposite second side of the interposer,
wherein the interposer has a rectangular configuration with rounded corners and at least one rounded side surface.

20. The semiconductor package of claim 19,
wherein the second underfill covers an outer portion of a first side of the package board and an inner portion of the stiffener.
